(19) United States
(12) Patent Application Publication
(10) Pub. No.: US 2017/0133572 A1
(43) Pub. Date: May 11, 2017

(54) THERMOELECTRIC MODULE

(71) Applicants: Esam Elsarrag, Doha (QA); Yousef Al-Horr, Doha (QA)

(72) Inventors: Esam Elsarrag, Doha (QA); Yousef Al-Horr, Doha (QA)

(21) Appl. No.: 15/322,491

(22) PCT Filed: Jul. 1, 2015
(86) PCT No.: PCT/GB2015/051923

§ 371 Date: Dec. 28, 2016

(30) Foreign Application Priority Data
Jul. 2, 2014 (GB) 1411817.8

(51) Int. Cl. H01L 35/32; E04B 1/76; E04C 2/52; H01L 35/30

(52) U.S. Cl. CPC H01L 35/32; H01L 35/30; E04B 1/76; E04C 2/525

(57) ABSTRACT

A thermoelectric module for use in a wall of a building, the thermoelectric module having a heat absorbing side and a heat dissipating side and including a plurality of thermoelectric legs extending there between. The thermoelectric legs are supported by channels provided in the support member. The legs are provided with heat absorbing interconnects and heat dissipating interconnects. The temperature difference across the thermoelectric legs causes electricity to be generated.

The present invention relates to a thermoelectric module, and in particular a thermoelectric module for attachment to a wall of a building.

In countries that have a particularly hot or cold climate, a building such as a house or an office may be built having a wall structure comprising internal and external walls separated by an air gap or cavity. This air gap reduces the overall heat transfer between the inside of the building and the outside of the building, due to the low thermal conductivity of air (around 0.0271 W/m·K compared to around 1.7 W/m·K for concrete). Accordingly, in a hot climate, where the sun delivers solar energy to the external walls of the building, the amount of heat or thermal energy transferred from the hot outside of the building to the cold inside of the building is reduced. Similarly, in a cold climate, the amount of heat or thermal energy transferred from the hot inside of the building to the cold outside of the building is reduced.

In order to further reduce this heat transfer to the inside of a building in a hot climate, it is possible to cool the outside wall by establishing an air flow in the cavity within the wall structure by use of a fan. However, such a fan requires an electrical power supply to operate, and consequently increases the building's complexity in that a connection to the mains electrical grid is then required.

To address this issue, it had been proposed that solar panels or thermoelectric modules might potentially offer a local power supply for driving air circulation within wall cavities. Indeed, even without the need to power a local fan, such energy recovery technology integrated into a wall structure could offer improved efficiency gains by reducing heat transferred through the wall. However, there are a number of issues preventing the adoption of these. Firstly, the use of solar panels requires substantive modification to the wall exterior, which therefore increases expense and limits where such panels may be used. Thermoelectric modules potentially offer more straightforward integration into a wall structure. However, conventional thermoelectric modules are not particularly effective at generating electricity in this application. The present inventors have recognised that the reason for this is that conventional thermoelectric modules are conventionally used for very high temperature applications, such as in ovens or commercial furnaces. Accordingly, until now, thermoelectric modules have been designed to operate with a ΔT of over 200° C. As such, when attempts have been made to use this technology within a wall structure, where the ΔT is typically in the region of 20° C.-30° C., the power generated is comparatively low.

Furthermore, the present inventors have also identified that since conventional thermoelectric modules are provided as small and rigid components, they are difficult to fit on to a wall structure. As such, further efficiency is lost by establishing poor heat transfer with a wall, not least because the surface of the wall structure often covers a much larger area and may be uneven.

The present invention seeks to overcome or mitigate the above problems associated with the prior art.

According to an aspect of the present invention, there is provided a thermoelectric module for use in a wall of a building comprising:

a thermoelectric generator having a heat absorbing side and a heat dissipating side and comprising a plurality of thermoelectric legs extending therebetween; and

a support member for supporting the thermoelectric legs, provided between the heat absorbing side and heat dissipating side.

With this arrangement, the provision of the support member in the middle of the module between the heat absorbing side and heat dissipating side allows these sides of the thermoelectric generator to be positioned in a more superficial location and thereby absorb and dissipate heat more effectively, whilst at the same time allowing the support member to support the thermoelectric legs and protect them from damage. This contrasts with conventional thermoelectric modules where the generator is embedded within the interior of a rigid support encapsulant, which surrounds its heat absorbing and heat dissipating sides. This encapsulant thereby presents a barrier to heat transfer to the thermoelectric legs.

In this connection, the central support provided with the present invention allows the heat absorbing side to be positioned closer to, or even in direct contact with, the wall of a building, which is acting as a heat source. This therefore allows a greater heat transfer to it.

Similarly, the heat dissipating side is also more exposed, thereby improving its heat dissipation.

As such, the temperature differential (ΔT) between the heat absorbing and heat dissipating sides is maximised.

The present invention is therefore able to generate electricity more effectively at the ΔT typically found within a wall structure of a building.

Preferably, the heat absorbing side and the heat dissipating side comprise conductive interconnects provided alternately on opposing ends of the thermoelectric legs to connect the plurality of thermoelectric legs in series.

Preferably, each conductive interconnect on the heat dissipating side comprises a shaped section that projects outward from a plane defined by the conductive interconnects on the heat dissipating side. Preferably, the shaped section is concertina shaped or corrugated. In this way, the increased surface area of the shaped section provides for a greater heat transfer between the heat dissipating conductive interconnects and passing airflow, allowing for heat to quickly dissipate. At the same time, the shaped section provides the thermoelectric module with greater flexibility as the folds in the section between the legs allows for relative movement between the connected legs. This in turn allows the module to maintain closer contact with uneven surfaces, thereby increasing the heat transferred to the thermoelectric module.

Preferably, the support member is partially flexible for maintaining contact between the heat absorbing side and a surface of the wall of a building. In this way, the thermoelectric module is able to bend to conform to uneven wall surfaces. This provides improved contact for increasing heat transfer.

Preferably, the conductive interconnects provided on the heat absorbing side are formed as flat strips. In this way, the conductive interconnects present a flat plane, increasing their surface area in contact with the heated wall surface.

Preferably, the edges of each of the plurality of conductive interconnects extend beyond the ends of the respective thermoelectric legs to which it is connected. In this way, the interconnects provide their connected thermoelectric leg with an increased heat transfer surface area.

Preferably, each of the plurality of conductive interconnects are metal or metallic.

Preferably, the plurality of conductive interconnects provided on the heat absorbing side and/or the heat dissipating side are exposed on the outside of the module. In this way, the conductive interconnects are able to directly absorb or dissipate heat to an adjacent heat source or air flow with no barrier to impede this heat flow. The heat absorbing side is therefore able to absorb heat from the wall surface faster, increasing the temperature of this side of the thermoelectric module, whilst at the same time, the heat dissipating side is able to dissipate heat to the environment faster.

Preferably, the support member comprises a plurality of channels through which the legs are supported. In this way, the legs are housed securely within the channels in order to insulate them and prevent damage.

Preferably, the thermoelectric module further comprises a mounting for securing the heat absorbing side to a surface of the wall of a building. In this way, the mounting maintains contact with the wall surface to maximise the rate of heat transfer.

According to another aspect of the present invention, there is provided a wall panel for a building comprising a thermoelectric module according to any preceding claim.

According to another aspect of the present invention, there is provided a thermoelectric module for use in a wall of a building, comprising:

a plurality of thermoelectric legs connected in series by conductive interconnects provided alternately on opposing ends of the legs; and

a supporting member for supporting the thermoelectric legs, the supporting member being positioned between the planes defined by the conductive interconnects on the opposing ends of the legs.

Illustrative embodiments of the invention will now be described, with reference to the accompanying drawings in which:

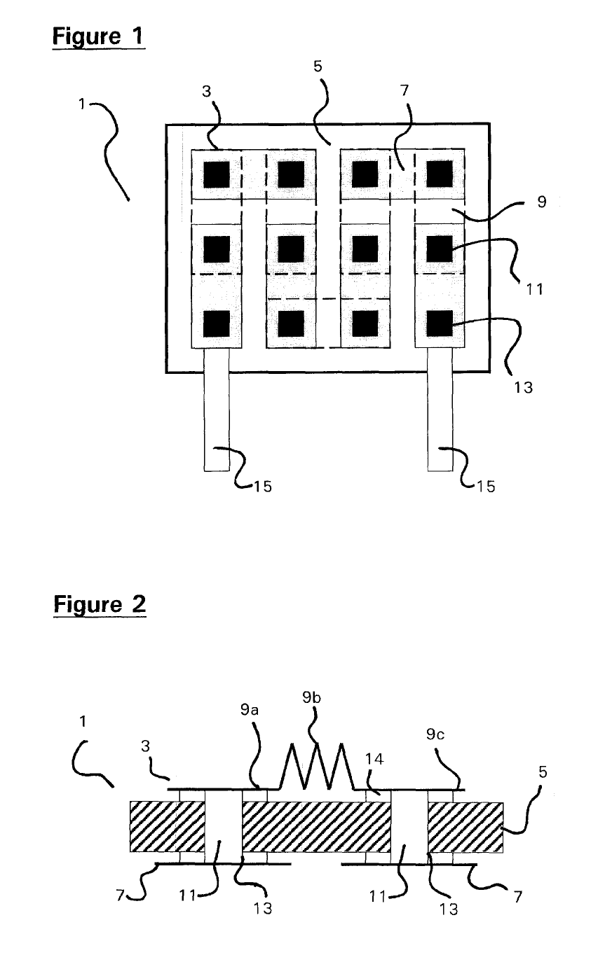

FIG. 1 shows a plan view of a thermoelectric module according to an embodiment of the invention;

FIG. 2 shows side cross sectional view of part of the thermoelectric module shown in FIG. 1; and

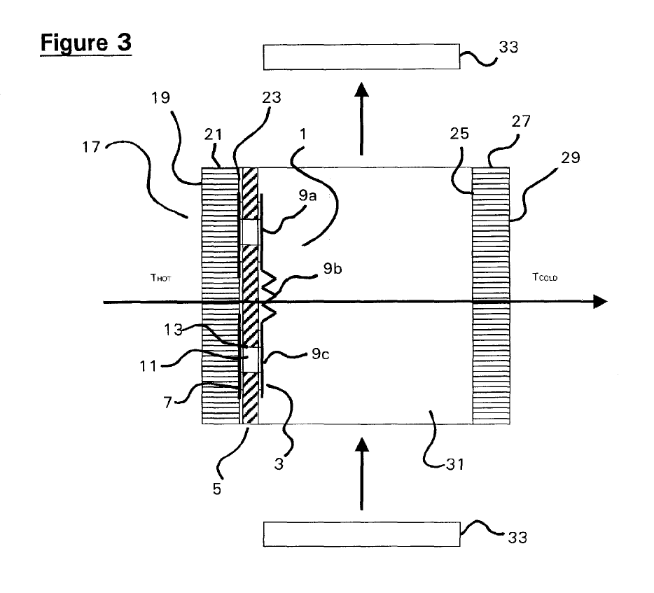

FIG. 3 shows a side cross sectional view of a section of a wall structure of a building incorporating a thermoelectric module according to an embodiment of the invention.

FIG. 1 shows a plan view of a thermoelectric module according to an embodiment of the invention. The thermoelectric module 1 has a generally planar configuration and comprises a thermoelectric generator 3 and a support member 5. The thermoelectric generator 3 comprises an array of thermoelectric legs 11 with a plurality of conductive interconnects 7, 9 provided alternately on opposing ends of the thermoelectric legs, such that the legs are connected electrically in series. In this way, the conductive interconnects define heat absorbing and heat dissipating sides of the module. FIG. 1 shows a view of the heat absorbing side of the thermoelectric generator 3 and therefore the heat absorbing side conductive interconnects can be seen. The heat dissipating side conductive interconnects 9 are on the reverse and are shown as dashed lines.

The thermoelectric legs 11 of the thermoelectric generator 3 are housed within channels 13 passing through the support member 5. Electrical leads 15 are provided for delivering electricity generated by the thermoelectric module 1.

FIG. 2 shows a cross section of part of the thermoelectric module 1 shown in FIG. 1.

The thermoelectric legs 11 pass through channels 13 provided in the support member 5. The height of the legs 11 is greater than the height of the support member 5 such that end faces of the legs 11 extend beyond and protrude from the support member 5. The conductive interconnects connect the ends of the legs through solder formed from metal or a metallic material. Sealant 14 is used to fill the gap between the support member 5 and the conductive interconnects 7, 9.

The thermoelectric legs 11 each have a high temperature side and a low temperature side. In FIG. 2 the heat absorbing side is provided with conductive interconnects 7 connected to the high temperature side of the legs 11, and the heat dissipating side is provided with conductive interconnects 9 connected to the low temperature side of the legs 11.

The heat absorbing interconnects 7 comprise flat strips and are formed from metal or a metallic material, presenting a flat plane for contact with the wall of a building, which is acting as a heat source.

The heat dissipating interconnect 9 shown in FIG. 2 comprises three sections. The outer sections comprising flat portions that present a flat plane 9a, 9c for connection to the end of the legs 11. Between these flattened sections is a central shaped section 9b, which forms an integral heat sink by providing an increased surface area. Specifically, the shaped section projects outward from the normal plane defined the two outer portions 9a, 9c forming a concertina shape. As such, the shaped section adopts a zig zag shape in profile.

FIG. 3 shows a side cross sectional view of a section of a wall structure 17 of a building incorporating the thermoelectric module 1 shown in FIG. 2. In this embodiment, the wall structure 17 is intended for use in a hot climate where the temperature outside of the building (T_{NOT}) is greater than the temperature inside of the building (T_{COLD}).

The wall structure 17 comprises an external layer 21 having an interior facing side 23 and an exterior facing side 19, and an internal layer 27 also having an interior facing side 29 and an exterior facing side 25. The two layers 21, 27 are separated by a cavity 31, through which air can flow. In FIG. 3 the air flow is driven due to the action of fans 33.

As can be seen, the thermoelectric module 1 is attached to the interior facing side 23 of the external layer 21 so that the heat absorbing conductive interconnects 7 are in direct contact with the interior facing side 23. The heat dissipating conductive interconnects 9 are therefore exposed within the cavity 31, with the concertina shape of the central section 9b exposed to the airflow within the cavity. The concertina shape also provides the thermoelectric module 1 with increased flexibility across its length such that it is able to maintain contact with the interior facing side 23, even if the wall structure's surface is uneven.

In use, warm outside air and radiation from the sun heats the exterior facing side 19 of the wall's external layer 21, increasing its temperature. The heat absorbed conducts through the external layer 21 where it is absorbed by the heat absorbing conductive interconnects 7 of the thermoelectric module 1. This increases their temperature, which then conducts through the thermoelectric legs 11 to the heat dissipating interconnects 9 on the heat dissipating side of the module 1. These are exposed within the cavity 31 and act as a heat sink. The lower temperature within the cavity causes heat to be rejected from the heat dissipating interconnects 9, thus cooling them and reducing the temperature of the connected low temperature side of the thermoelectric legs 11.

The temperature difference across the thermoelectric legs 11 causes electricity to be generated, which is output via leads 15 and which can then be used to power fans 33. This can, in turn, further cool the heat dissipating side of the thermoelectric module 1 to generate further electricity. Accordingly, no external source of electricity is required and the building's overall thermal management is improved.

It will be understood that the embodiment illustrated above shows applications of the invention only for the purposes of illustration. In practice the invention may be applied to many different configurations, the detailed embodiments being straightforward for those skilled in the art to implement.

For example, when the temperature of the inside of the building having the wall structure is higher than the temperature of the outside of the building, the thermoelectric module 1 may be attached to the outside 25 of the internal layer 27 by the heat absorbing side, such that the heat dissipating side is exposed within the cavity 31. This would allow the thermoelectric module to generate electricity using the heat of the inside of the building.

In addition, the air flow within the cavity 31 may not be caused by a fan 33. Instead, it may flow due to natural convention. Alternatively, the air within the cavity 31 may not flow and instead act as a static heat sink. Equally, electricity generated by the thermoelectric module need not be used to drive fans, but instead could be stored or used for other purposes, such as to power lighting.

1-11. (canceled)

12. A thermoelectric module for use in a wall of a building, comprising:
a) a thermoelectric generator having a heat absorbing side and a heat dissipating side and comprising a plurality of thermoelectric legs extending there between; and
b) a support member for supporting the thermoelectric legs, provided between the heat absorbing side and heat dissipating side,
c) wherein the thermoelectric legs pass through channels provided in the support member and the height of the thermoelectric legs is greater than the height of the support member so that ends of the thermoelectric legs protrude from the support member; and
d) wherein the thermoelectric module further comprises sealant for scaling the thermoelectric legs at the gap between the support member and the conductive interconnects.

13. A thermoelectric module according to claim 12, wherein the heat absorbing side and the heat dissipating side comprise conductive interconnects provided alternately on opposing ends of the thermoelectric legs to connect the plurality of thermoelectric legs in series.

14. A thermoelectric module according to claim 13, wherein each conductive interconnect on the heat dissipating side comprises a shaped section that projects outward from a plane defined by the conductive interconnects on the heat dissipating side.

15. A thermoelectric module according to claim 12, wherein the support member is partially flexible for maintaining contact between the heat absorbing side and a surface of the wall of a building.

16. A thermoelectric module according to claim 13, wherein the conductive interconnects provided on the heat absorbing side are formed as flat strips.

17. A thermoelectric module according to claim 13, wherein the edges of each of the plurality of conductive interconnects extend beyond the ends of the respective thermoelectric legs to which it is connected.

18. A thermoelectric module according to claim 13, wherein the plurality of conductive interconnects provided on the heat absorbing side and/or the heat dissipating side are exposed on the outside of the module.

19. A thermoelectric module according to claim 14, wherein the shaped section is concertina shaped or corrugated.

20. A thermoelectric module according to claim 12, wherein the thermoelectric module further comprises a mounting for securing the heat absorbing side to a surface of the wall of a building.

21. A wall panel for a building comprising a thermoelectric module according to claim 12.
